(19) United States
(12) Patent Application Publication
(10) Pub. No.: US 2016/0047037 A1
(43) Pub. Date: Feb. 18, 2016

(54) FILM FORMATION METHOD

(71) Applicants: TOSHIBA MITSUBISHI-ELECTRIC INDUSTRIAL SYSTEMS CORPORATION, Chuo-ku, Tokyo (JP); KYOTO UNIVERSITY, Kyoto (JP); KOCHI PREFECTURAL PUBLIC UNIVERSITY CORPORATION, Kochi-shi, Kochi (JP)

(72) Inventors: Takahiro HIRAMATSU, Tokyo (JP); Hiroyuki ORITA, Tokyo (JP); Takahiro SHIRAHATA, Tokyo (JP); Shizyo FUJITA, Kyoto (JP); Toshiyuki KAWAHARAMURA, Kochi (JP)

(73) Assignees: TOSHIBA MITSUBISHI-ELECTRIC INDUSTRIAL SYSTEMS CORPORATION, Chuo-ku, Tokyo (JP); KYOTO UNIVERSITY, Kyoto-shi, Kyoto (JP); Kochi Prefectural Public University Corporation, Kochi-shi, Kochi (JP)

(21) Appl. No.: 14/782,229

(22) PCT Filed: Apr. 17, 2013
(86) PCT No.: PCT/JP2013/061401

§ 371 Date: Oct. 2, 2015

(51) Int. Cl. C23C 16/448; C23C 16/455; C23C 16/50

(52) U.S. Cl. CPC C23C 16/4486; C23C 16/50; C23C 16/455

(57) ABSTRACT

In a film formation method, a mist of a solution is sprayed onto a substrate to form a film on the substrate. A film formation is then suspended. The substrate is then exposed to plasma.

### TECHNICAL FIELD

The present invention relates to a film formation method for forming a film on a substrate.

### BACKGROUND ART

It is known that active species generated in the gas phase are, for example, absorbed, diffused, and chemically react on a surface of a substrate to form a thin film on the substrate. As a method for forming a thin film on a substrate, mist chemical vapor deposition (CVD) and other methods are used. In the mist CVD, a mist of a solution is sprayed onto a substrate in the atmosphere to form a thin film on the substrate. The mist CVD is described, for example, in Patent Document 1.

### PRIOR ART DOCUMENT

### Patent Document

Patent Document 1: Japanese Patent Application Laid-Open Publication No. 2010-197723

### SUMMARY OF INVENTION

### Problems to be Solved by the Invention

When the above-mentioned absorption, diffusion, chemical reaction, and the like are inadequate, vacancies are formed in the film, and the film is contaminated with impurities, leading to reduction of denseness of the resulting film. Reduction of film density is also a major problem in the above-mentioned mist CVD. Especially in the mist CVD, the majority of reaction energy required for film formation is dependent on thermal energy obtained from the substrate being heated. For this reason, the above-mentioned reduction of film density becomes noticeable when film formation is performed by CVD while the substrate is heated to 200° C. or lower.

It is an object of the present invention to provide a film formation method allowing for improvement in film density.

### Means for Solving the Problems

In order to achieve the above-mentioned object, a film formation method according to the present invention includes the steps of: (A) spraying a mist of a solution onto a substrate to form a film on the substrate; (B) suspending the step (A); and (C) after the step (B), exposing the substrate to plasma.

### Effects of the Invention

The film formation method according to the present invention includes the steps of: (A) spraying a mist of a solution onto a substrate to form a film on the substrate; (B) suspending the step (A); and (C) after the step (B), exposing the substrate to plasma.

As a result, the film having improved density and a predetermined thickness is formed on the substrate. Furthermore, stabilization of active species can be promoted, and denseness (densification) of the film can be improved by plasma exposure.

Objects, features, aspects and advantages of the present invention will become more apparent from the following detailed description and the accompanying drawings.

### BRIEF DESCRIPTION OF DRAWINGS

FIG. 1 is a cross section for describing a film formation method according to an embodiment.

FIG. 2 is a cross section for describing the film formation method according to the embodiment.

FIG. 3 is a cross section for describing the film formation method according to the embodiment.

FIG. 4 is a diagram for describing the effects of a film formation method according to the present invention.

FIG. 5 is a diagram for describing the effects of the film formation method according to the present invention.

### DESCRIPTION OF EMBODIMENTS

The present invention is applicable to a film formation method for forming a film on a substrate by performing mist CVD in the atmosphere. The present invention is described specifically based on the drawings showing an embodiment of the present invention.

### Embodiment

FIGS. 1-3 are cross sections for describing a film formation method according to the present embodiment. As can be seen from FIGS. 1-3, a film formation apparatus implementing the present invention includes a mist spray nozzle 1 and a plasma exposure nozzle 2. The following describes a detail of the film formation method according to the present embodiment with use of the drawings.

A substrate 10 as a target for film formation is placed on a substrate mount, which is not shown in FIGS. 1-3. The substrate mount is provided with a heater, and the substrate 10 is heated to approximately 200° C. The substrate 10 is positioned below the mist spray nozzle 1 as shown in FIG. 1.

A mist (droplets have been reduced to approximately several micrometers) of a solution produced with an ultrasonic transducer and the like is sprayed from the mist spray nozzle 1. The solution contains raw materials for the film formed on the substrate 10. In the state shown in FIG. 1, the mist of the solution is rectified, and sprayed from the mist spray nozzle 1 onto the substrate 10 under atmospheric pressure (film formation).

In spraying the mist of the solution, the substrate mount is driven horizontally to move the substrate 10 horizontally. By performing spraying while moving the substrate 10 horizontally, the mist of the solution is sprayed onto the entire upper surface of the substrate 10. A thin film 15 having a small thickness is formed on the entire upper surface of the substrate 10 by spraying the mist of the solution.

Next, spraying of the solution is suspended (suspension of film formation).

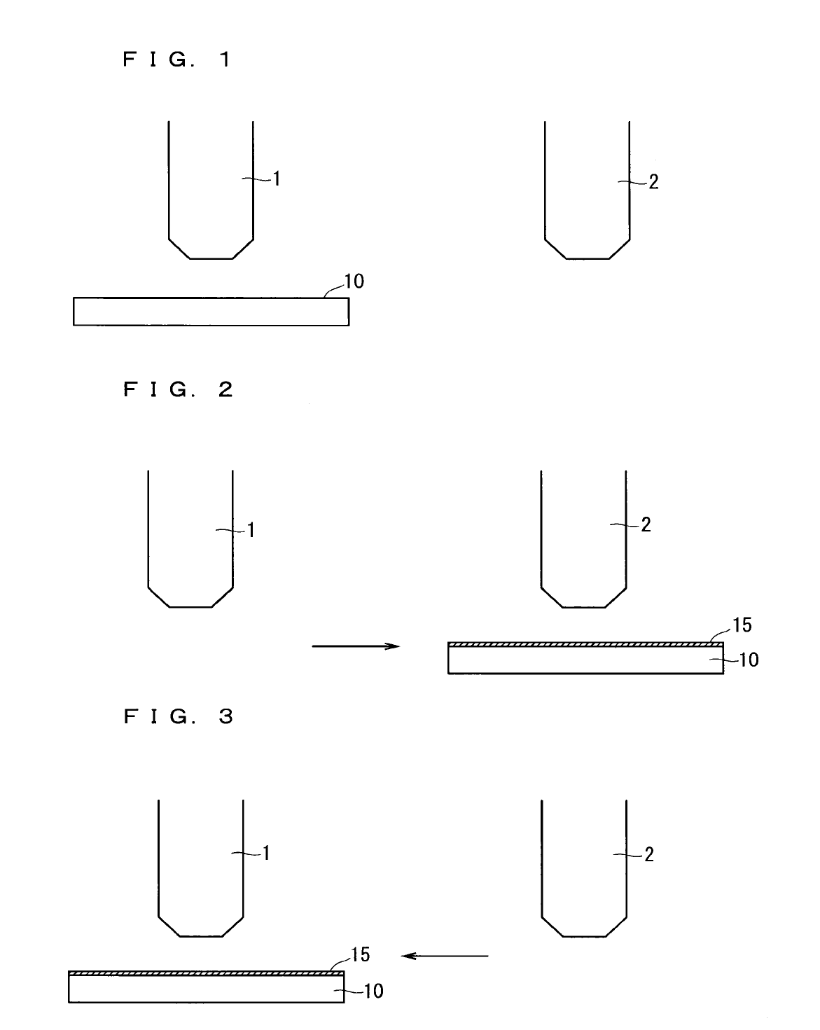

Spraying of the solution onto the substrate 10 can be suspended, for example, by driving the substrate mount horizontally to move the substrate 10 from a spraying region in which the solution is sprayed to a non-spraying region in which the solution is not sprayed, as shown in FIG. 2. As shown in FIG. 2, the plasma exposure nozzle 2 is placed in the non-spraying region, and, in the non-spraying region, the substrate 10 is positioned below the plasma exposure nozzle 2.

Plasma is generated by applying a voltage to a plasma generating gas, and the plasma exposure nozzle 2 can expose the substrate 10 to the generated plasma (the plasma exposure nozzle 2 is a so-called plasma torch). In the state shown in FIG. 2, the substrate 10 on which the thin film 15 has been formed is exposed to plasma with use of the plasma exposure nozzle 2 under atmospheric pressure (plasma exposure).

In plasma exposure, the substrate mount is driven horizontally to move the substrate 10 horizontally. By performing plasma exposure while moving the substrate 10 horizontally, the entire upper surface of the substrate 10 (more specifically, the thin film 15) can be exposed to plasma.

The substrate 10 is heated by the heater of the substrate mount also in the plasma exposure. Examples of the plasma generating gas are gas containing a noble gas, and gas containing an oxidizing agent (e.g., oxygen and nitrous oxide).

When a metal oxide film or the like is formed as the thin film 15, oxidation can be promoted in a plasma exposure period by using the oxidizing agent as the plasma generating gas.

On the other hand, by using the noble gas as the plasma generating gas, contamination, attributable to plasma exposure, of the thin film 15 formed by film formation can be prevented in the plasma exposure period.

Next, plasma exposure is suspended (suspension of plasma exposure).

Plasma exposure of the substrate 10 can be suspended, for example, by driving the substrate mount horizontally to move the substrate 10 from the above-mentioned non-spraying region to the above-mentioned spraying region (the region not affected by plasma exposure performed with use of the plasma exposure nozzle 2), as shown in FIG. 3. As shown in FIG. 3, the mist spray nozzle 1 is placed in the spraying region as in FIG. 1. In the spraying region, the substrate 10 is positioned below the mist spray nozzle 1 as shown in FIG. 3.

Then, in the state shown in FIG. 3, the mist of the solution is sprayed onto the substrate 10 on which the thin film 15 has been formed and which has been exposed to plasma (this can be construed as the second film formation), as described with use of FIG. 1. The substrate 10 is heated by the heater of the substrate mount also in the second film formation.

As described above, a series of steps consisting of film formation, suspension of film formation, plasma exposure, and suspension of plasma exposure performed in the stated order is set to one cycle, and the series of steps is repeated for at least two cycles. This means that intermittent film formation is performed onto the substrate 10, and plasma exposure is performed in a period in which film formation is not performed.

For example, repeating the above-mentioned series of steps for three cycles means that film formation, suspension of film formation, plasma exposure, suspension of plasma exposure, film formation, suspension of film formation, plasma exposure, suspension of plasma exposure, film formation, suspension of film formation, plasma exposure, and suspension of plasma exposure are performed in the stated order.

As described above, in the film formation method according to the present embodiment, film formation is intermittently performed to form (deposit) the film 15 on the substrate 10, and a non-film formation period is provided between film formation periods.

The thin film 15 deposited on the surface of the substrate 10 is thus stabilized in the above-mentioned non-film formation period. Furthermore, solvent and other substances contained in the solution are efficiently vaporized, for example, from the substrate 10 in the non-film formation period. This improves denseness of the thin film 15, and, as a result, the film having improved density and a predetermined thickness is formed on the substrate 10.

Contrary to the description made above, the non-film formation period may be a period in which only heating of the substrate 10 is performed without performing plasma exposure. That is to say, film formation is suspended, the substrate 10 is allowed to stand in the atmosphere for a predetermined period, and only heating of the substrate 10 is performed. Improvement in denseness (densification) of the thin film 15 can also be achieved by this method.

In the film formation method according to the present embodiment, however, the substrate 10 is exposed to plasma in the above-mentioned non-film formation period as described above. This promotes stabilization of active species, and further improves denseness (densification) of the thin film 15.

It is desirable to perform plasma exposure in the atmosphere only in the non-film formation period without performing plasma exposure in the film formation period as described above, rather than perform plasma exposure in the atmosphere in the film formation period. This is because of the following reason: when plasma exposure is performed in the atmosphere in the film formation period, reaction in the gas phase becomes more dominant than reaction on the surface of the substrate 10, which is a target for film formation, and, as a result, the solution is not turned into a film but is turned into powders. Occurrence of the above-mentioned problem can be prevented by performing plasma exposure in the atmosphere only in the non-film formation period as described above.

Denseness of the thin film 15 is improved as the thickness of the thin film 15 formed in a single film formation period decreases.

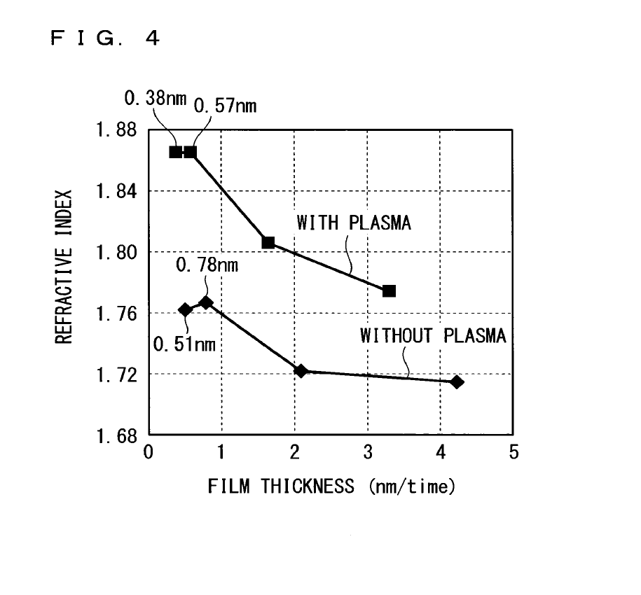

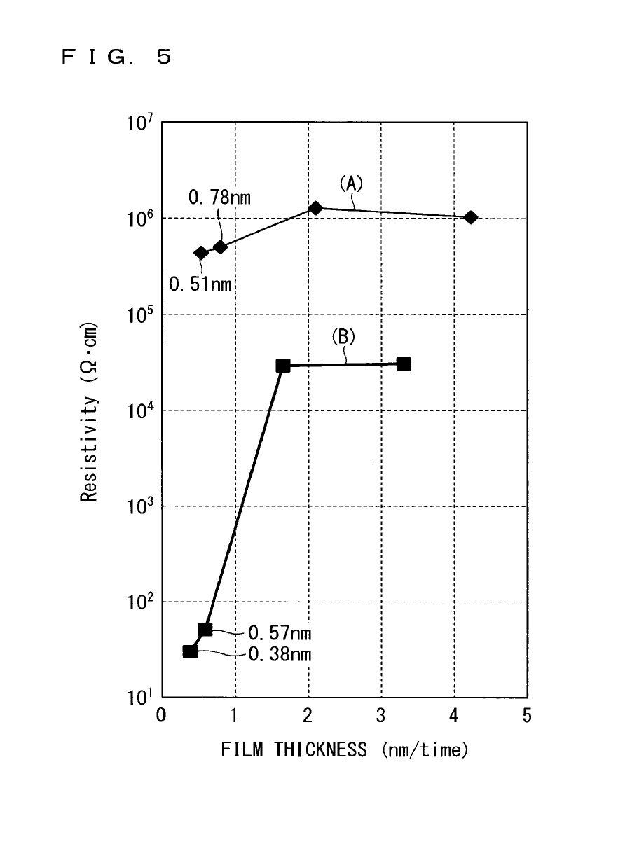

FIGS. 4 and 5 are experimental data for describing each of the above-mentioned effects.

FIG. 4 is experimental data showing a relationship between the thickness of the thin film 15 formed in a single film formation process and a refractive index. The vertical axis in FIG. 4 represents the refractive index of the formed thin film 15, and the horizontal axis in FIG. 4 represents the thickness (nm/time) of the thin film 15 formed in a single film formation process. FIG. 4 shows experimental data (squares) obtained when plasma exposure is performed in the non-film formation period, and experimental data (rhombi) obtained when plasma exposure is not performed in the non-film formation period.

FIG. 5 is experimental data showing a relationship between the thickness of the thin film 15 formed in a single film formation process and resistivity. The vertical axis in FIG. 5 represents resistivity (Ω·cm) of the formed thin film 15, and the horizontal axis in FIG. 5 represents the thickness (nm/time) of the thin film 15 formed in a single film formation process. A mark “A” in FIG. 5 represents experimental data obtained when plasma exposure is not performed in the non-film formation period. A mark “B” in FIG. 5 represents experimental data obtained when plasma exposure is performed in the non-film formation period.

In experiments in which the results shown in FIGS. 4 and 5 are obtained, the substrate 10 is heated to 200° C., and the thin film 15 formed on the substrate 10 is a zinc oxide film in a series of film formation steps (the film formation period and the non-film formation period).

An increase in refractive index of the zinc oxide film typically indicates improvement in denseness (densification) of the zinc oxide film. As can be seen from the experimental data shown in FIG. 4, the refractive index increases as the thickness of the thin film 15 formed in the single film formation process decreases in both of the case where plasma exposure is performed and the case where plasma exposure is not performed. That is to say, it is confirmed that denseness (densification) of the zinc oxide film is improved as the thickness of the zinc oxide film formed in the single film formation process decreases in both of the case where plasma exposure is performed and the case where plasma exposure is not performed.

It is also confirmed from the experimental data shown in FIG. 4 that denseness (densification) of the zinc oxide film is improved more in the case where plasma exposure is performed in the non-film formation period than in the case where plasma exposure is not performed in the non-film formation period.

As can be seen from the experimental data shown in FIG. 5, resistivity decreases as the thickness of the thin film 15 formed in the single film formation process decreases in both of the case where plasma exposure is performed and the case where plasma exposure is not performed. This trend is caused presumably because “denseness (densification) of the zinc oxide film is improved as the thickness of the zinc oxide film formed in the single film formation process decreases”, as confirmed in FIG. 3.

It is also confirmed from comparison between the experimental data “A” shown in FIG. 5 and the experimental data “B” shown in FIG. 5 that resistivity of the zinc oxide film decreases more in the case where plasma exposure is performed in the non-film formation period than in the case where plasma exposure is not performed in the non-film formation period.

It is also confirmed from FIGS. 4 and 5 that, in the case where plasma exposure is not performed in the non-film formation period, denseness (densification) of the zinc oxide film becomes noticeable when the thickness is 0.78 nm or smaller, and, in the case where plasma exposure is performed in the non-film formation period, denseness (densification) of the zinc oxide film becomes noticeable when the thickness is 0.57 nm or smaller.

Although FIGS. 4 and 5 show results obtained in the case where the thin film 15 is the zinc oxide film, when the thin film 15 is a film other than the zinc oxide film, denseness of the thin film 15 is improved as the thickness of the thin film 15 formed in the single film formation period decreases, and denseness (densification) of the thin film 15 is improved more in the case where plasma exposure is performed in the non-film formation period than in the case where plasma exposure is not performed in the non-film formation period.

In terms of reducing the thickness of the thin film 15 formed in the single film formation period, it is preferable to set the above-mentioned series of steps to one cycle, and to repeat the series of steps for at least two cycles.

This is because of the following reason: if a target thickness of the film eventually formed on the substrate 10 is determined, the thickness of the thin film 15 formed in a single film formation period can decrease and denseness of the entire film eventually formed on the substrate 10 can be improved by increasing the number of cycles for which the series of steps is repeated until the thickness reaches the target thickness.

As described above, denseness of the thin film 15 is improved as the thickness of the thin film 15 formed in the single film formation period decreases. It is thus important to control film formation conditions (heating temperature and the amount of mist solution supply) during film formation, the film formation period, and the like so that the thickness of the thin film 15 formed in the single film formation period decreases. If the thickness of the thin film 15 formed in the single film formation period can be measured, it is desirable to measure the thickness and to suspend the film formation period when the thickness reaches a desired thickness.

In the above-mentioned description, film formation is suspended by moving the substrate 10 from the spraying region in which the solution is sprayed to the non-spraying region in which the solution is not sprayed. Alternatively, film formation may be suspended by stopping and starting spraying of the solution (turning on and off spraying of the solution) from the mist spray nozzle 1 onto the substrate 10.

Similarly, in the above-mentioned description, plasma exposure is suspended by moving the substrate 10 from the non-spraying region to the spraying region (the region not affected by plasma exposure). Alternatively, plasma exposure may be suspended by turning on and off plasma exposure from the plasma exposure nozzle 2.

While the present invention has been described in detail, the foregoing description is in all aspects illustrative and not restrictive. It is therefore understood that numerous modifications that have not been described can be devised without departing from the scope of the present invention.

### REFERENCE SIGNS LIST

1 mist spray nozzle
2 plasma exposure nozzle
10 substrate
15 thin film

1. A film formation method comprising the steps of:
(A) spraying a mist of a solution onto a substrate (10) to form a film on said substrate;
(B) suspending said step (A); and
(C) after said step (B), exposing said substrate to plasma.

2. The film formation method according to claim 1, further comprising the step of
(D) suspending said step (C), wherein
a series of steps from said step (A) to said step (D) is set to one cycle, and the series of steps is repeated for at least two cycles.

3. The film formation method according to claim 1, wherein
said step (B) is a step of moving said substrate from a spraying region in which said solution is sprayed to a non-spraying region in which said solution is not sprayed.

4. The film formation method according to claim 1, wherein
said step (B) is a step of stopping spraying of said solution onto said substrate.

5. The film formation method according to claim 1, wherein
said step (C) is a step of performing exposure to said plasma with use of gas containing a noble gas as a plasma generating gas.

6. The film formation method according to claim 1, wherein
said step (C) is a step of performing exposure to said plasma with use of gas containing an oxidizing agent as a plasma generating gas.
